(19) United States
(12) Patent Application Publication
(10) Pub. No.: US 2008/0102572 A1
(43) Pub. Date: May 1, 2008

(54) Manufacturing method of semiconductor device

(75) Inventor: Hirotaka Komatsubara, Miyagi (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/905,914

(22) Filed: Oct. 5, 2007

(30) Foreign Application Priority Data
Oct. 25, 2006 (JP) 2006-290370

(51) Int. Cl. H01L 21/8238

(52) U.S. Cl. 438/199; 257/E21.632

(57) ABSTRACT

The present invention provides a method of manufacturing a semiconductor device, which is simple in manufacturing process and easy to control formed positions of a tensile film and a compressive film and their thicknesses. An n-type MOSFET and a p-type MOSFET are formed on a semiconductor substrate, and the tensile film is formed on the n-type MOSFET. Thereafter, a protective film is formed on the entire surface of the semiconductor substrate. After a compressive film is formed on the protective film, the compressive film provided on the n-type MOSFET is removed by etching using the protective film as an etching stopper.

### BACKGROUND OF THE INVENTION

The present invention relates to a method for manufacturing a semiconductor device having MOSFETs. More specifically, the present invention relates to a method for manufacturing a semiconductor device having MOSFETs, which has adopted a distortion silicon technology.

A MOSFET (Metal Oxide Semiconductor Field Effect Transistor) using a distortion silicon technology has heretofore been known. The distortion silicon technology is of a technique for applying a compressive stress or a tensile stress to a channel region thereby to improve drive capacity of the MOSFET.

When a compressive stress in a gate-length direction is applied to a channel region, an on current increases in a pMOSFET. On the other hand, when a tensile stress in a gate-length direction is applied to the channel region, an on current increases in an nMOSFET. Thus, a CMOSFET high in drive capacity can be obtained by applying the compressive stress to the pMOSFET and applying a tensile stress to an nMOSFET (refer to, for example, the paragraph 0002 of a patent document 1 (Japanese Unexamined Patent Publication No. 2006-80161)).

Therefore, in the MOSFETs disclosed in the patent document 1, an insulating film (hereinafter described as “compressive film”) having a compressive stress is formed in the surface of the pMOSFET, and an insulating film (hereinafter described as “tensile film”) having a tensile stress is formed in the surface of the nMOSFET (refer to the paragraph 0004 and FIG. 1 and the like in the patent document 1).

In MOSFETs disclosed in a patent document 2 (Japanese Unexamined Patent Publication No. 2004-63591), a compressive film or a tensile film is embedded in each device isolation trench thereby to apply a compressive stress to a pMOSFET and apply a tensile stress to an nMOSFET (refer to, for example, the paragraph 0029 of the patent document 2).

Now, as a method for forming a compressive film and a tensile film in the surface of each MOSFET or each trench thereof, the following methods are known.

In the manufacturing method disclosed in the patent document 1, a tensile film is formed on the entire surface of a wafer and thereafter the tensile film provided on a pMOSFET forming region is selectively removed. Thereafter, a compressive film is formed on the entire surface of the wafer. Further, the compressive film provided on a pMOSFET forming region is selectively removed (refer to the paragraph 0050 of the patent document 1).

In the technique disclosed in the patent document 2, a compressive film is formed on the entire surface of a wafer. Thereafter, the compressive film provided on an nMOSFET forming region is selectively removed. Further, a tensile film is formed on the entire surface of the wafer and thereafter the entire wafer is etched back, thereby removing the compressive film and the tensile film formed other than each trench (refer to the paragraphs 0015 to 0021 and FIGS. 1 and 2 in the patent document 2).

However, the manufacturing method disclosed in the patent document 1 has the drawbacks that since it includes a step of selectively removing the tensile film and a step of selectively removing the compressive film, a resist forming step is required twice, and hence a manufacturing process becomes complex and position displacement is easy to occur.

On the other hand, the manufacturing method disclosed in the patent document 2 is hard to cause problems such as complexity of a manufacturing process and the occurrence of position displacement because the selectively removing step is provided only once. However, the manufacturing method has the drawback that since the region formed with the compressive film alone and the region formed with both the compressive film and the tensile film are simultaneously etched back, it is difficult to control each thickness with a high degree of accuracy.

### SUMMARY OF THE INVENTION

The present invention has been made in view of the foregoing. It is therefore an object of the present invention to provide a method of manufacturing a semiconductor device, which is simple in manufacturing process and easy to control formed positions of a tensile film and a compressive film and their thicknesses.

According to a first aspect of the present invention, for attaining the above object, there is provided a method for manufacturing a semiconductor device in which the surface of a first conduction type field effect transistor is covered with a first stress film having one of a tensile stress and a compressive stress and the surface of a second conduction type field effect transistor of a conduction type opposite to a first conduction type is covered with a second stress film having the other thereof.

The present method includes a first step for forming the first conduction type field effect transistor and the second conduction type field effect transistor over a semiconductor substrate, a second step for forming the first stress film over the entire surface of the semiconductor substrate, a third step for removing a portion covering the second conduction type field effect transistor, of the first stress film by etching, a fourth step for forming a protective film over the entire surface of the semiconductor substrate, a fifth step for forming the second stress film over the protective film, and a sixth step for performing etching until the second stress film provided over the first conduction type field effect transistor is removed, using the protective film as an etching stopper.

According to a second aspect of the present invention, for attaining the above object, there is provided a method for manufacturing a semiconductor device in which the surface of a first conduction type field effect transistor is covered with a first stress film having one of a tensile stress and a compressive stress and the surface of a second conduction type field effect transistor of a conduction type opposite to a first conduction type is covered with a second stress film having the other thereof.

The present method includes a first step for forming the first conduction type field effect transistor and the second conduction type field effect transistor over a semiconductor substrate, a second step for forming the first stress film over the entire surface of the semiconductor substrate, a third step for removing a portion covering the second conduction type field effect transistor, of the first stress film by etching, a fourth step for forming the second stress film over the entire surface of the semiconductor substrate, and a fifth step for performing polishing using a chemical mechanical polishing method until the second stress film provided over the first conduction type field effect transistor is removed.

According to a third aspect of the present invention, for attaining the above object, there is provided a method for manufacturing a semiconductor device wherein the surface of an n-type field effect transistor is covered with a first stress film having a tensile stress and the surface of a p-type field effect transistor is covered with a second stress film having a compressive stress.

The present method includes a first step for forming the n-type field effect transistor and the p-type field effect transistor over a semiconductor substrate, a second step for forming the first stress film over the entire surface of the semiconductor substrate, a third step for forming a mask pattern in a portion covering the n-type field effect transistor, of the first stress film, and a fourth step for selectively implanting argon ions in a region for forming the p-type field effect transistor, using the mask pattern thereby to transform the first stress film into the second stress film.

According to the first aspect of the present invention, the second stress film is formed after the surface of the first stress film is covered with the protective film, and the second stress film is etched back using the protective film as the etching stopper. Therefore, a manufacturing process can be simplified and control on the formed positions and thicknesses of the first and second stress films is easy.

According to the second aspect of the present invention, the second stress film formed in the surface of the first stress film is removed using a chemical mechanical vapor polishing method. Therefore, a manufacturing process can be simplified and control on the formed positions and thicknesses of the first and second stress films is easy.

According to the third aspect of the present invention, the second stress film is formed by implanting argon ions into the first stress film formed on the pMOSFET. Therefore, a manufacturing process can be simplified and control on the formed positions and thicknesses of the first and second stress films is easy.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a sectional process diagram showing a manufacturing method according to a first embodiment;

FIG. 2 is a sectional process diagram illustrating the manufacturing method according to the first embodiment;

FIG. 3 is a sectional process diagram depicting a manufacturing method according to a second embodiment;

FIG. 4 is a sectional process diagram showing the manufacturing method according to the second embodiment; and

FIG. 5 is a sectional process diagram illustrating a manufacturing method according to a third embodiment.

### DETAILED DESCRIPTION OF THE PREFERRED EMBODIMENTS

Preferred embodiments of the present invention will hereinafter be described with reference to the accompanying drawings. Incidentally, the size, shape and physical relationship of each constituent element or component in the figures are merely approximate illustrations to enable an understanding of the present invention. Numerical conditions to be described below are nothing more than mere preferred examples.

### First Preferred Embodiment

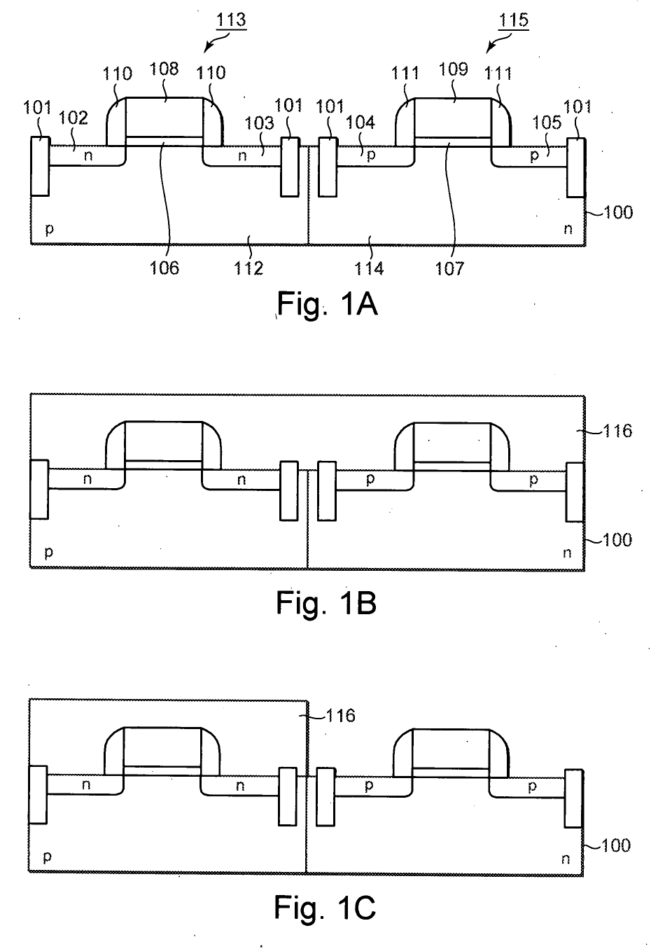

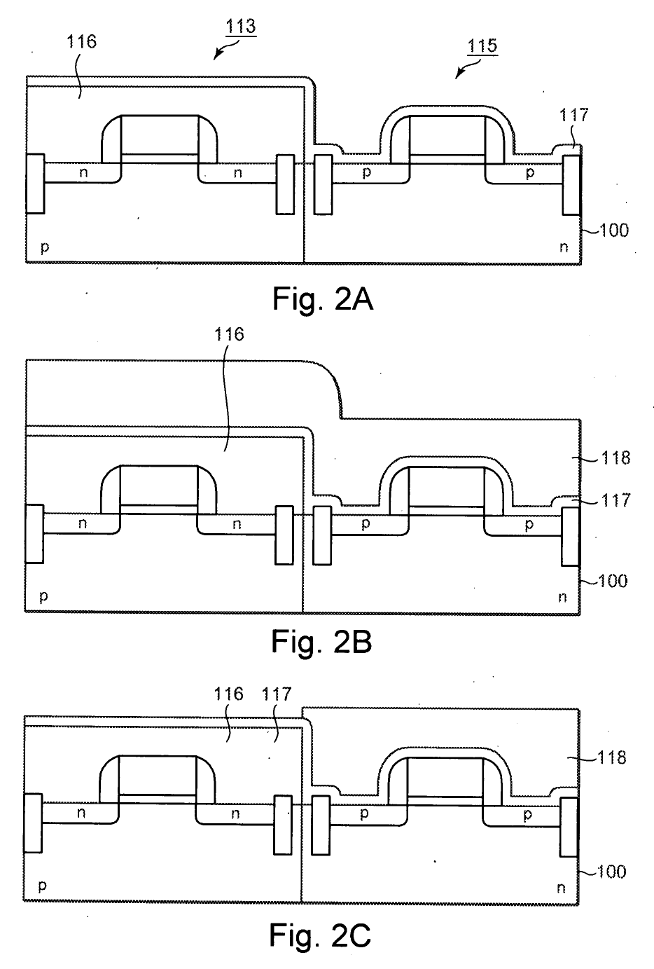

A method of manufacturing a semiconductor device, according to a first embodiment of the present invention will be explained using FIGS. 1 and 2.

FIGS. 1 and 2 are sectional process diagrams showing the manufacturing method according to the present embodiment.

(1) Device isolation regions 101, n-type diffusion regions 102 and 103, p-type diffusion regions 104 and 105, gate insulating films 106 and 107, gate electrodes 108 and 109, and sidewalls 110 and 111 are first formed on the surface of a semiconductor substrate 100 by a known manufacturing process (refer to FIG. 1(A)). Thus, an nMOSFET 113 is formed in a p-type region 112 of the semiconductor substrate 100, and a pMOSFET 115 is formed in an n-type region 114 thereof, respectively.

(2) A thin film (i.e., tensile film) 116 having tensile stress is formed on the entire surface of the semiconductor substrate 100 (refer to FIG. 1(B)). Si₃N₄ is deposited at 600 to 800° C. using, for example, an LP-CVD (Low Pressure-Chemical Vapor Deposition) method, thereby making it possible to generate tensile stress in this Si₃N₄ film. The thickness of the tensile film 116 is preferably 50 nm or more, for example. This is because the tensile stress can be increased as the thickness of the tensile film 116 becomes larger. However, there is a limit to the size of its thickness in terms of structural restrictions or the like on the semiconductor device. Thus, the thickness of the tensile film 116 is preferably set so as to normally range from over 50 nm to under 150 nm.

(3) A resist mask is next formed on the p-type region 112 of the semiconductor substrate 100. The tensile film 116 provided on the n-type region 114 is removed by etching. Thereafter, the resist mask is removed (refer to FIG. 1(C)).

(4) An etching stopper film 117 is formed on the entire surface of the semiconductor substrate 100 (refer to FIG. 2(A)). Thus, the entire surfaces of the tensile film 116 and the pMOSFET 115 are covered with the etching stopper film 117. For example, a silicon oxide film can be adopted as the etching stopper film 117. The thinner the thickness of the etching stopper film 117 the more desirable. Its thickness is 5 nm or less, for example.

(5) Subsequently, a thin film (i.e., compressive film) 118 having compressive stress is formed on the entire surface of the semiconductor substrate 100 (refer to FIG. 2(B)). Si₃N₄ is deposited at 500° C. or less using, for example, a plasma CVD method, thereby making it possible to generate compressive stress in this Si₃N₄ film. It is desirable that the thickness of the compressive film 118 is normally set so as to range from over 50 nm to under 150 nm due to the same reason as the case of the above tensile film 116. However, the thickness of the tensile film 116 and the thickness of the compressive film 118 need not be necessarily coincident with each other.

(6) Finally, the compressive film 118 is etched using a known etching method. This etching is done until the compressive film 118 provided on the nMOSFET 113 is removed (refer to FIG. 2(C)). Since the etching stopper film 117 is used, the tensile film 116 is not etched by this etching.

In the present embodiment as described above, the surface of the tensile film 116 is covered with the etching stopper film 117 and thereafter the formation and etchback of the compressive film 118 are done. Thus, since selective etching may be done once, a manufacturing process is simple and control on the formed positions of the films 116 and 118 is easy. Since only the compressive film 118 is etched upon this etchback, control on the thicknesses of the films 116 and 118 is easy.

Incidentally, an aluminium oxide film can also be used as the compressive film 118 in place of the Si₃N₄ film in the present embodiment. Compressive stress can be applied to a channel forming region of the semiconductor substrate 100 using expansion action of aluminium oxide.

### Second Preferred Embodiment

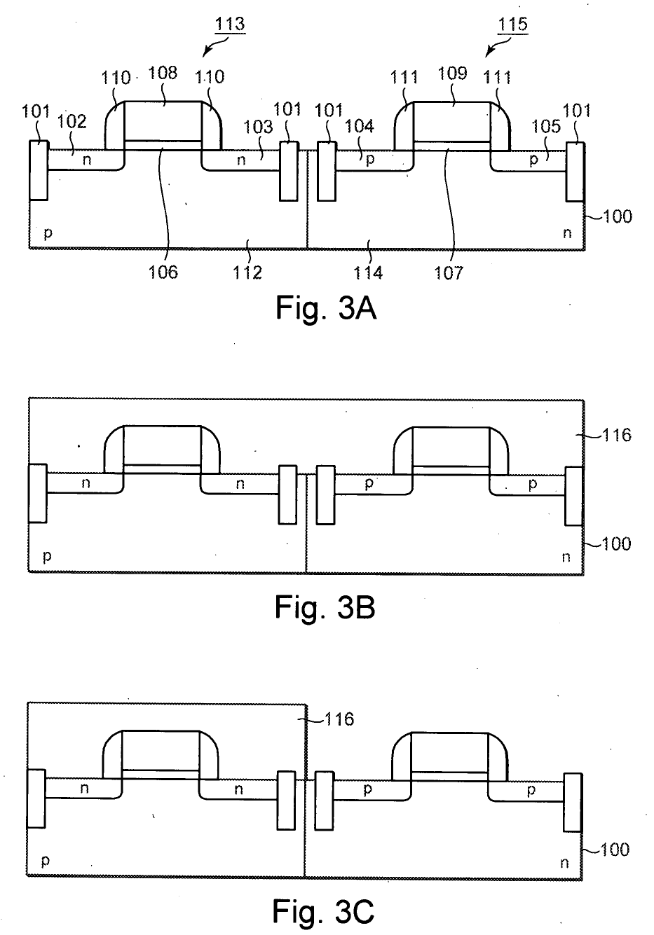

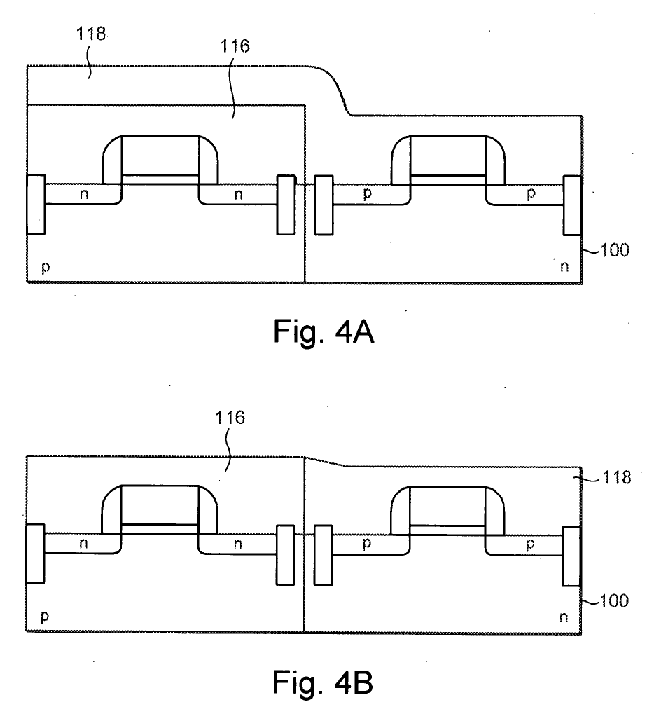

A method of manufacturing a semiconductor device, according to a second embodiment of the present invention will next be explained using FIGS. 3 and 4.

FIGS. 3 and 4 are respectively sectional process diagrams showing the manufacturing method according to the present embodiment. In FIGS. 3 and 4, constituent elements marked with the same reference numerals as those in FIGS. 1 and 2 respectively indicate the same ones as those in FIGS. 1 and 2.

(1) An nMOSFET 113 and a pMOSFET 115 are first formed on the surface of a semiconductor substrate 100 in a manner similar to the first embodiment (refer to FIG. 3(A)).

(2) Next, a tensile film 116 is formed on the entire surface of the semiconductor substrate 100 under a deposition or growth condition similar to the first embodiment using the LP-CVD method (refer to FIG. 3(B)). The thickness of the tensile film 116 is preferably set so as to normally range from over 50 nm to under 150 nm due to the same reason as the first embodiment.

(3) A resist mask is next formed on a p-type region 112 of the semiconductor substrate 100. The tensile film 116 provided on an n-type region 114 is removed by etching. Thereafter, the resist mask is removed (refer to FIG. 3(C)).

(4) Subsequently, a compressive film 118 is formed on the entire surface of the semiconductor substrate 100 under the same deposition condition as the first embodiment using the plasma CVD method (refer to FIG. 3(A)). Although the thickness of the compressive film 118 is preferably set to normally range from over 50 nm to under 150 nm due to the same reason as the first embodiment, it is not necessary to allow the thickness of the compressive film 118 to coincide with the thickness of the tensile film 116.

(5) Finally, the compressive film 118 is polished using a chemical mechanical polishing (CMP) method. This polishing is done until the compressive film 118 provided on the nMOSFET 113 is at least removed (refer to FIG. 3(B)).

According to the present embodiment as described above, the compressive film 118 formed on the surface of the tensile film 116 is removed using the CMP method. Thus, since selective etching may be done once, a manufacturing process can be simplified and control on the formed positions of the tensile film 116 and compressive film 118 is easy. Since the CMP method is used, thickness control is easy.

Incidentally, an aluminium oxide film can also be used as the compressive film 118 in place of the Si₃N₄ film in a manner similar to the first embodiment.

### Third Preferred Embodiment

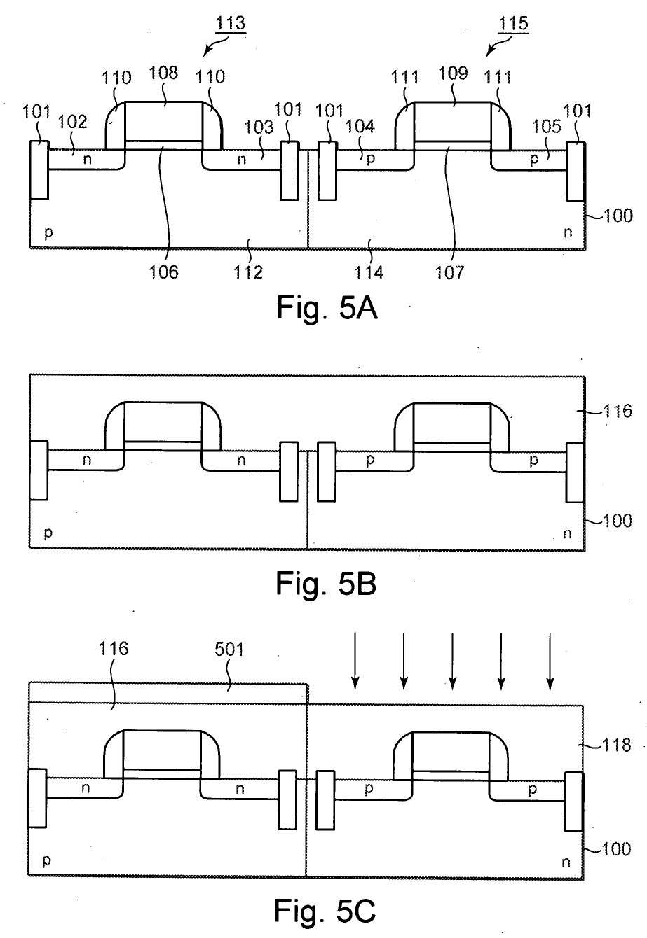

A method of manufacturing a semiconductor device, according to a third embodiment of the present invention will next be explained using FIG. 5.

FIG. 5 is a sectional process diagram showing the manufacturing method according to the present embodiment. In FIG. 5, constituent elements marked with the same reference numerals as those in FIGS. 1 and 2 respectively indicate the same ones as those in FIGS. 1 and 2.

(1) An nMOSFET 113 and a pMOSFET 115 are first formed on the surface of a semiconductor substrate 100 in a manner similar to the first embodiment (refer to FIG. 5(A)).

(2) Next, a tensile film 116 is formed on the entire surface of the semiconductor substrate 100 under a deposition or growth condition similar to the first embodiment using the LP-CVD method (refer to FIG. 5(B)). The thickness of the tensile film 116 is preferably set so as to range from over 100 nm to under 150 nm.

(3) Next, a mask pattern 501 is formed on a p-type region 112 of the semiconductor substrate 100. Argon ions are selectively implanted into a region for forming the pMOSFET 115 using the mask pattern 501 (refer to FIG. 5(C)). Thus, the tensile film 116 provided on the pMOSFET 115′ can be transformed into a compressive film 118. The amount of ion implantation may preferably be 1×10¹⁵ cm⁻², for example. Energy to be implanted is preferably set to 50 to 100 keV. When the energy to be implanted is excessively small, only the surface of the tensile film 116 is altered or transformed, so that sufficient compressive stress cannot be obtained. When the energy to be implanted is excessively large, it exerts a bad influence on the characteristic of a gate electrode 109.

According to the present embodiment as described above, a manufacturing process can be simplified because argon ions are implanted into the tensile film 116 formed on the pMOSFET 115 thereby to form the compressive film 118 (refer to the above process step (3)). Since the compressive film 118 can be formed by the selective ion implantation, control on the formed positions and thicknesses of the films 116 and 118 is easy.

While the preferred forms of the present invention have been described, it is to be understood that modifications will be apparent to those skilled in the art without departing from the spirit of the invention. The scope of the invention is to be determined solely by the following claims.

What is claimed is:

1. A method for manufacturing a semiconductor device in which the surface of a first conduction type field effect transistor is covered with a first stress film having one of a tensile stress and a compressive stress and the surface of a second conduction type field effect transistor of a conduction type opposite to a first conduction type is covered with a second stress film having the other thereof, comprising the following steps:
a first step for forming the first conduction type field effect transistor and the second conduction type field effect transistor over a semiconductor substrate;
a second step for forming the first stress film over the entire surface of the semiconductor substrate;
a third step for removing a portion covering the second conduction type field effect transistor, of the first stress film by etching;
a fourth step for forming a protective film over the entire surface of the semiconductor substrate;
a fifth step for forming the second stress film over the protective film; and
a sixth step for performing etching until the second stress film provided over the first conduction type field effect transistor is removed, using the protective film as an etching stopper.

2. The method according to claim 1, wherein either one having the compressive stress, of the first and second stress films is an aluminium oxide film.

3. A method for manufacturing a semiconductor device in which the surface of a first conduction type field effect transistor is covered with a first stress film having one of a tensile stress and a compressive stress and the surface of a second conduction type field effect transistor of a conduction type opposite to a first conduction type is covered with a second stress film having the other thereof, comprising the following steps:
a first step for forming the first conduction type field effect transistor and the second conduction type field effect transistor over a semiconductor substrate;
a second step for forming the first stress film over the entire surface of the semiconductor substrate;
a third step for removing a portion covering the second conduction type field effect transistor, of the first stress film by etching;
a fourth step for forming the second stress film over the entire surface of the semiconductor substrate; and
a fifth step for performing polishing using a chemical mechanical polishing method until the second stress film provided over the first conduction type field effect transistor is removed.

4. The method according to claim 3, wherein either one having the compressive stress, of the first and second stress films is an aluminium oxide film.

5. A method for manufacturing a semiconductor device wherein the surface of an n-type field effect transistor is covered with a first stress film having a tensile stress and the surface of a p-type field effect transistor is covered with a second stress film having a compressive stress, comprising the following steps:
a first step for forming the n-type field effect transistor and the p-type field effect transistor over a semiconductor substrate;
a second step for forming the first stress film over the entire surface of the semiconductor substrate;
a third step for forming a mask pattern in a portion covering the n-type field effect transistor, of the first stress film; and
a fourth step for selectively implanting argon ions in a region for forming the p-type field effect transistor, using the mask pattern thereby to transform the first stress film into the second stress film.

6. The method according to claim 5, wherein implantation energy at the implantation of the argon ions ranges from over 50 keV to under 100 keV.
